(19) United States
(12) Patent Application Publication
(10) Pub. No.: US 2025/0389800 A1
(43) Pub. Date: Dec. 25, 2025

(54) MODEL-BASED DEEP LEARNING METHOD AND SYSTEM FOR DENOISING MAGNETIC RESONANCE IMAGES

(71) Applicant: GE Precision Healthcare LLC, Waukesha, WI (US)

(72) Inventors: Sudhanya Chatterjee, Bangalore (IN); Robert Marc Lebel, Calgary (CA)

(21) Appl. No.: 18/752,061

(22) Filed: Jun. 24, 2024

(51) Int. Cl. G01R 33/56; G06T 5/60; G06T 5/70; G06T 7/00; G06T 11/00

(52) U.S. Cl. CPC G01R 33/5608; G06T 5/60; G06T 5/70; G06T 7/0012; G06T 11/006; G06T 2207/10088; G06T 2207/20081; G06T 2207/20084; G06T 2207/30004; G06T 2210/41

(57) ABSTRACT

A computer-implemented method includes obtaining, via a processing system including one or more processors, noisy k-space data of a subject acquired with a magnetic resonance imaging (MRI) scanner. The computer-implemented method also includes utilizing, via the processing system, a deep learning-based mask estimating model to estimate a data consistency mask based on a frequency content of the noisy k-space data, wherein the data consistency mask is configured to be utilized in denoising the noisy k-space data in a model-based deep learning manner. The computer-implemented method further includes utilizing, via the processing system, a deep learning-based reconstruction model on the noisy k-space data to generate a reconstructed denoised image utilizing the data consistency mask.

### BACKGROUND

The subject matter disclosed herein relates to medical imaging and, more particularly, to a model-based deep learning method and system for denoising magnetic resonance images.

Non-invasive imaging technologies allow images of the internal structures or features of a patient/object to be obtained without performing an invasive procedure on the patient/object. In particular, such non-invasive imaging technologies rely on various physical principles (such as the differential transmission of X-rays through a target volume, the reflection of acoustic waves within the volume, the paramagnetic properties of different tissues and materials within the volume, the breakdown of targeted radionuclides within the body, and so forth) to acquire data and to construct images or otherwise represent the observed internal features of the patient/object.

During magnetic resonance imaging (MRI), when a substance such as human tissue is subjected to a uniform magnetic field (polarizing field B₀), the individual magnetic moments of the spins in the tissue attempt to align with this polarizing field, but precess about it in random order at their characteristic Larmor frequency. If the substance, or tissue, is subjected to a magnetic field (excitation field B₁) which is in the x-y plane and which is near the Larmor frequency, the net aligned moment, or “longitudinal magnetization”, M_{z}, may be rotated, or “tipped”, into the x-y plane to produce a net transverse magnetic moment, Mt. A signal is emitted by the excited spins after the excitation signal B₁ is terminated and this signal may be received and processed to form an image.

When utilizing these signals to produce images, magnetic field gradients (Gₓ, G_{y}, and G_{z}) are employed. Typically, the region to be imaged is scanned by a sequence of measurement cycles in which these gradient fields vary according to the particular localization method being used. The resulting set of received nuclear magnetic resonance (NMR) signals are digitized and processed to reconstruct the image using one of many well-known reconstruction techniques.

The artificial intelligence-based denoising techniques used today are blind denoising techniques. This means that a deep learning-based model is exposed to a wide range of noisy images and the deep learning network learns to detect noise in the images (e.g. in an image in and image out training setup). However, in situations where the signal-to-noise ratio of the noise image is very low (or beyond the limits on which the deep learning-based model has been trained on), blind denoising techniques falter by over smoothening noisy image (i.e., effacing structures) in lieu of detecting noise.

### BRIEF DESCRIPTION

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a computer-implemented method is provided. The computer-implemented method includes obtaining, via a processing system including one or more processors, noisy k-space data of a subject acquired with a magnetic resonance imaging (MRI) scanner. The computer-implemented method also includes utilizing, via the processing system, a deep learning-based mask estimating model to estimate a data consistency mask based on a frequency content of the noisy k-space data, wherein the data consistency mask is configured to be utilized in denoising the noisy k-space data in a model-based deep learning manner. The computer-implemented method further includes utilizing, via the processing system, a deep learning-based reconstruction model on the noisy k-space data to generate a reconstructed denoised image utilizing the data consistency mask.

In another embodiment, a system is provided. The system includes a memory encoding processor-executable routines. The system also includes a processing system including one or more processors and configured to access the memory and to execute the processor-executable routines, wherein the process-executable routines, when executed by the processing system, cause the processing system to perform actions. The actions include obtaining noisy k-space data of a subject acquired with a magnetic resonance imaging (MRI) scanner. The actions also include utilizing a deep learning-based mask estimating model to estimate a data consistency mask based on a frequency content of the noisy k-space data, wherein the data consistency mask is configured to be utilized in denoising the noisy k-space data in a model-based deep learning manner. The actions further include utilize a deep learning-based reconstruction model on the noisy k-space data to generate a reconstructed denoised image utilizing the data consistency mask.

In a further embodiment, a non-transitory computer-readable medium, the computer-readable medium including processor-executable code that when executed by a processing system including one or more processors, causes the processing system to perform actions. The actions include obtaining noisy k-space data of a subject acquired with a magnetic resonance imaging (MRI) scanner. The actions also include utilizing a deep learning-based mask estimating model to estimate a data consistency mask based on a frequency content of the noisy k-space data, wherein the data consistency mask is configured to be utilized in denoising the noisy k-space data in a model-based deep learning manner. The actions further include utilize a deep learning-based reconstruction model on the noisy k-space data to generate a reconstructed denoised image utilizing the data consistency mask.

### BRIEF DESCRIPTION OF THE DRAWINGS

These and other features, aspects, and advantages of the present subject matter will become better understood when the following detailed description is read with reference to the accompanying drawings in which like characters represent like parts throughout the drawings, wherein:

FIG. 1 illustrates a schematic diagram of a magnetic resonance imaging (MRI) system suitable for use with the disclosed techniques, in accordance with aspects of the present disclosure;

FIG. 2 is a schematic diagram illustrating reconstruction utilizing an estimated data consistency mask, in accordance with aspects of the present disclosure;

FIG. 3 is a schematic diagram of a method for estimating a data consistency mask (e.g., without parametric assertions made), in accordance with aspects of the present disclosure;

FIG. 4 is a schematic diagram of a method for estimating a data consistency mask (e.g., with strong parametric assertions made), in accordance with aspects of the present disclosure;

FIG. 5 illustrates a flow diagram of a method for image processing of MR data, in accordance with aspects of the present disclosure;

FIG. 6 depicts analysis of MR data utilizing the techniques described herein, in accordance with aspects of the present disclosure;

FIG. 7 depicts analysis of a zoomed in portion of the MR data in FIG. 6, in accordance with aspects of the present disclosure;

FIG. 8 depicts analysis of MR data utilizing the techniques described herein (e.g., in a very signal-to-noise ratio case), in accordance with aspects of the present disclosure;

FIG. 9 depicts MR data obtained utilizing the techniques described herein, in accordance with aspects of the present disclosure;

FIG. 10 depicts MR data obtained utilizing the techniques described herein (e.g., of the brain with T2 fluid attenuated inversion recovery (FLAIR)), in accordance with aspects of the present disclosure;

FIG. 11 depicts MR data obtained utilizing the techniques described herein (e.g., of the brain with T1 fast spin echo (FSE)), in accordance with aspects of the present disclosure;

FIG. 12 depicts MR data obtained utilizing the techniques described herein (e.g., of the cervical spine with T1 FSE), in accordance with aspects of the present disclosure;

FIG. 13 depicts MR data obtained utilizing the techniques described herein (e.g., of the cervical spine with T2 short tau inversion recovery (STIR)), in accordance with aspects of the present disclosure;

FIG. 14 depicts MR data obtained utilizing the techniques described herein (e.g., of the knee with T1 FSE), in accordance with aspects of the present disclosure;

FIG. 15 depicts MR data obtained utilizing the techniques described herein (e.g., of the shoulder with T1 FSE), in accordance with aspects of the present disclosure;

FIG. 16 depicts MR data obtained utilizing the techniques described herein (e.g., of the neck with sagittal T2 STIR), in accordance with aspects of the present disclosure;

FIG. 17 depicts MR data obtained utilizing the techniques described herein (e.g., of the neck with coronal T2 STIR), in accordance with aspects of the present disclosure;

FIG. 18 depicts noisy MR data compared to MR data denoised utilizing the techniques described herein (e.g., of the knee with T1 FSE), in accordance with aspects of the present disclosure;

FIG. 19 depicts noisy MR data compared to MR data denoised utilizing the techniques described herein (e.g., of the knee with sagittal T1 FSE), in accordance with aspects of the present disclosure;

FIG. 20 depicts noisy MR data compared to MR data denoised utilizing the techniques described herein (e.g., of the knee with axial T1 FSE), in accordance with aspects of the present disclosure;

FIG. 21 depicts noisy MR data compared to MR data denoised (with controlled denoising for high signal-to-noise ratio images) utilizing the techniques described herein (e.g., of the knee with axial T1 FSE), in accordance with aspects of the present disclosure;

FIG. 22 depicts noisy MR data compared to MR data denoised (with controlled denoising for high signal-to-noise ratio images) utilizing the techniques described herein (e.g., of the knee with sagittal T1 FSE), in accordance with aspects of the present disclosure; and

FIG. 23 depicts noisy MR data compared to MR data denoised (with controlled denoising for high signal-to-noise ratio images) utilizing the techniques described herein (e.g., of the knee with coronal T1 FSE), in accordance with aspects of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present subject matter, the articles “a,” “an,” “the,” and “said” are intended to mean that there are one or more of the elements. The terms “comprising,” “including,” and “having” are intended to be inclusive and mean that there may be additional elements other than the listed elements. Furthermore, any numerical examples in the following discussion are intended to be non-limiting, and thus additional numerical values, ranges, and percentages are within the scope of the disclosed embodiments.

While aspects of the following discussion are provided in the context of medical imaging, it should be appreciated that the disclosed techniques are not limited to such medical contexts. Indeed, the provision of examples and explanations in such a medical context is only to facilitate explanation by providing instances of real-world implementations and applications. However, the disclosed techniques may also be utilized in other contexts, such as image reconstruction for non-destructive inspection of manufactured parts or goods (i.e., quality control or quality review applications), and/or the non-invasive inspection of packages, boxes, luggage, and so forth (i.e., security or screening applications). In general, the disclosed techniques may be useful in any imaging or screening context or image processing or photography field where a set or type of acquired data undergoes a reconstruction process to generate an image or volume.

Deep learning (DL) approaches discussed herein may be based on artificial neural networks, and may therefore encompass one or more of deep neural networks, fully connected networks, convolutional neural networks (CNNs), transformer-based networks, unrolled neural networks, perceptrons, encoders-decoders, recurrent networks, wavelet filter banks, u-nets, general adversarial networks (GANs), dense neural networks, or other neural network architectures. The neural networks may include shortcuts, activations, batch-normalization layers, and/or other features. These techniques are referred to herein as DL techniques, though this terminology may also be used specifically in reference to the use of deep neural networks, which is a neural network having a plurality of layers.

As discussed herein, DL techniques (which may also be known as deep machine learning, hierarchical learning, or deep structured learning) are a branch of machine learning techniques that employ mathematical representations of data and artificial neural networks for learning and processing such representations. By way of example, DL approaches may be characterized by their use of one or more algorithms to extract or model high level abstractions of a type of data-of-interest. This may be accomplished using one or more processing layers, with each layer typically corresponding to a different level of abstraction and, therefore potentially employing or utilizing different aspects of the initial data or outputs of a preceding layer (i.e., a hierarchy or cascade of layers) as the target of the processes or algorithms of a given layer. In an image processing or reconstruction context, this may be characterized as different layers corresponding to the different feature levels or resolution in the data. In general, the processing from one representation space to the next-level representation space can be considered as one ‘stage’ of the process. Each stage of the process can be performed by separate neural networks or by different parts of one larger neural network.

Blind denoising (image to image only) has the difficulty in generalizing the task of estimating the noise amplitude and/or coloring, which limits performance, especially in low signal-to-noise ratio situations and in situations for which data driven training is not sufficient. Traditionally, denoising is solved as inverse problem with the forward operator in the forward model considered as the identity.

Generally speaking, an observed MRI k-space data (y) can be expressed as, y=MFS, where S is the underlying image, F is the Fourier operation, and M is the sampling mask. M·F is often referred to as the data consistency term. In this document, M is also referred to as the data consistency mask. For multi-coil data, S is expressed as S=CP, where C is the coil sensitivity data and P is the multi-coil data.

The present disclosure provides systems and methods for performing model-based denoising of magnetic resonance images while estimating the regions where to remain consistent in the noisy k-space data. Hence, the forward model for denoising is not considered as identity in this case. An unrolled algorithm-based deep learning framework is utilized for denoising the image. In particular, provided a noisy k-space, the disclosed techniques estimate the frequencies which need to be perturbed (or otherwise) to denoise the data in a model-based deep learning framework. The disclosed techniques enable obtaining the optimum degree of k-space perturbance required for denoising an MR image in an unrolled/model-based framework. The problem of denoising is treated as a reconstruction problem (instead of image in and image out). Unlike an undersampled reconstruction problem where there is a binary mask which composed the data consistency term, the data consistency mask in the in the present disclosure shall not be necessarily binary, but instead have some continuous form which is able to obtain an image with high signal-to-noise ratio representation of the noisy input image. In particular, in the present disclosure, a continuous data consistency mask is estimated for model-based deep learning denoising. Also, the present disclosure utilizes an MRI signal model-based approach to denoise magnetic resonance images. This is different from approaches where image and image out denoising networks are trained for magnetic resonance images (which are agnostic to the signal model by which MR images are formed). The disclosed network follows the MRI signal model, while utilizing data learnt priors. This makes the disclosed techniques more explainable and has a lesser chance of providing unreliable outputs.

The disclosed techniques estimate the frequency weights by virtue of which the data consistency in the unrolled technique is observed. Unlike acceleration (where the frequency points sampled and otherwise are known), in the technique of denoising, this information is not known. Hence, performing a model-based reconstruction is not trivial. In the disclosed techniques, these frequency weights that are estimated (unlike acceleration) are not binary but continuous (e.g., in a variable or value range between 0 and 1. By doing so, the disclosed techniques estimates the way the frequency space of the noisy image should be modulated by the output of the deep learning-based regularizer. An important consequence of this is that each MR image has an estimation for the data-consistency mask which suits its frequency content the best.

The disclosed embodiments provide high image quality images which improves the diagnostic quality of the images (and potentially reduces image reading times). The disclosed embodiments also provide the ability to reliably denoise very low signal-to-noise ratio images. This provides the ability to have diagnostic quality images from high resolution single average magnetic resonance imaging data (thus, providing better quality images from less scan time). This also provides reliable performance for sequence which operate in low signal-to-noise regimes.

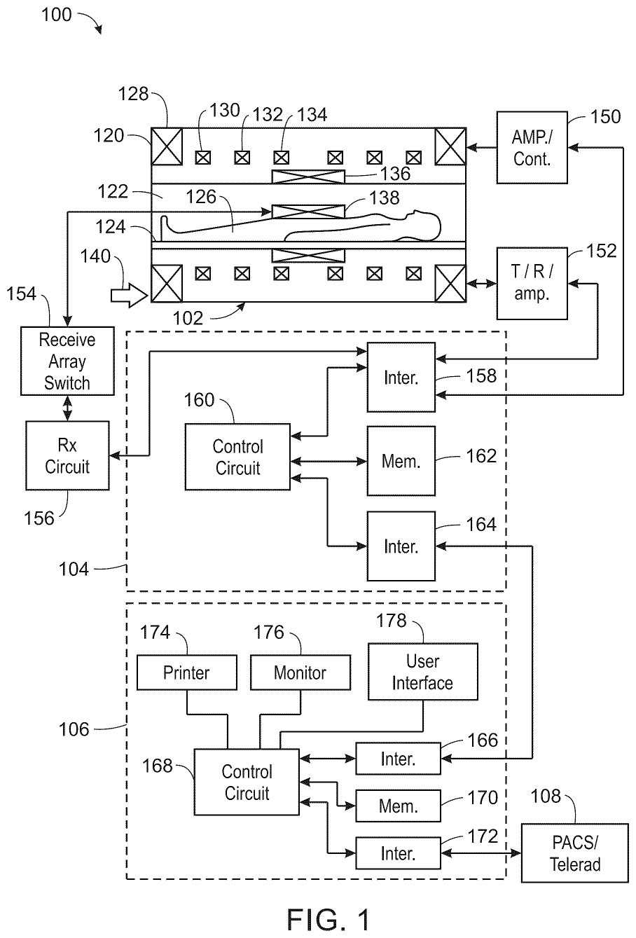

With the preceding in mind, FIG. 1 a magnetic resonance imaging (MRI) system 100 is illustrated schematically as including a scanner 102, scanner control circuitry 104, and system control circuitry 106. According to the embodiments described herein, the MRI system 100 is generally configured to perform MR imaging.

System 100 additionally includes remote access and storage systems or devices such as picture archiving and communication systems (PACS) 108, or other devices such as teleradiology equipment so that data acquired by the system 100 may be accessed on- or off-site. In this way, MR data may be acquired, followed by on- or off-site processing and evaluation. While the MRI system 100 may include any suitable scanner or detector, in the illustrated embodiment, the system 100 includes a full body scanner 102 having a housing 120 through which a bore 122 is formed. A table 124 is moveable into the bore 122 to permit a patient 126 (e.g., subject) to be positioned therein for imaging selected anatomy within the patient.

Scanner 102 includes a series of associated coils for producing controlled magnetic fields for exciting the gyromagnetic material within the anatomy of the patient being imaged. Specifically, a primary magnet coil 128 is provided for generating a primary magnetic field, B₀, which is generally aligned with the bore 122. A series of gradient coils 130, 132, and 134 permit controlled magnetic gradient fields to be generated for positional encoding of certain gyromagnetic nuclei within the patient 126 during examination sequences. A radio frequency (RF) coil 136 (e.g., RF transmit coil) is configured to generate radio frequency pulses for exciting the certain gyromagnetic nuclei within the patient. In addition to the coils that may be local to the scanner 102, the system 100 also includes a set of receiving coils or RF receiving coils 138 (e.g., an array of coils) configured for placement proximal (e.g., against) to the patient 126. As an example, the receiving coils 138 can include cervical/thoracic/lumbar (CTL) coils, head coils, single-sided spine coils, and so forth. Generally, the receiving coils 138 are placed close to or on top of the patient 126 so as to receive the weak RF signals (weak relative to the transmitted pulses generated by the scanner coils) that are generated by certain gyromagnetic nuclei within the patient 126 as they return to their relaxed state.

The various coils of system 100 are controlled by external circuitry to generate the desired field and pulses, and to read emissions from the gyromagnetic material in a controlled manner. In the illustrated embodiment, a main power supply 140 provides power to the primary field coil 128 to generate the primary magnetic field, B₀. A power input (e.g., power from a utility or grid), a power distribution unit (PDU), a power supply (PS), and a driver circuit 150 may together provide power to pulse the gradient field coils 130, 132, and 134. The driver circuit 150 may include amplification and control circuitry for supplying current to the coils as defined by digitized pulse sequences output by the scanner control circuitry 104.

Another control circuit 152 is provided for regulating operation of the RF coil 136. Circuit 152 includes a switching device for alternating between the active and inactive modes of operation, wherein the RF coil 136 transmits and does not transmit signals, respectively. Circuit 152 also includes amplification circuitry configured to generate the RF pulses. Similarly, the receiving coils 138 are connected to switch 154, which is capable of switching the receiving coils 138 between receiving and non-receiving modes. Thus, the receiving coils 138 resonate with the RF signals produced by relaxing gyromagnetic nuclei from within the patient 126 while in the receiving mode, and they do not resonate with RF energy from the transmitting coils (i.e., coil 136) so as to prevent undesirable operation while in the non-receiving mode. Additionally, a receiving circuit 156 is configured to receive the data detected by the receiving coils 138 and may include one or more multiplexing and/or amplification circuits.

It should be noted that while the scanner 102 and the control/amplification circuitry described above are illustrated as being coupled by a single line, many such lines may be present in an actual instantiation. For example, separate lines may be used for control, data communication, power transmission, and so on. Further, suitable hardware may be disposed along each type of line for the proper handling of the data and current/voltage. Indeed, various filters, digitizers, and processors may be disposed between the scanner and either or both of the scanner and system control circuitry 104, 106.

As illustrated, scanner control circuitry 104 includes an interface circuit 158, which outputs signals for driving the gradient field coils and the RF coil and for receiving the data representative of the magnetic resonance signals produced in examination sequences. The interface circuit 158 is coupled to a control and analysis circuit 160. The control and analysis circuit 160 executes the commands for driving the circuit 150 and circuit 152 based on defined protocols selected via system control circuit 106.

Control and analysis circuit 160 also serves to receive the magnetic resonance signals and performs subsequent processing before transmitting the data to system control circuit 106. Scanner control circuit 104 also includes one or more memory circuits 162, which store configuration parameters, pulse sequence descriptions, examination results, and so forth, during operation.

Interface circuit 164 is coupled to the control and analysis circuit 160 for exchanging data between scanner control circuitry 104 and system control circuitry 106. In certain embodiments, the control and analysis circuit 160, while illustrated as a single unit, may include one or more hardware devices. The system control circuit 106 includes an interface circuit 166, which receives data from the scanner control circuitry 104 and transmits data and commands back to the scanner control circuitry 104. The control and analysis circuit 168 may include a CPU in a multi-purpose or application specific computer or workstation. Control and analysis circuit 168 is coupled to a memory circuit 170 to store programming code for operation of the MRI system 100 and to store the processed image data for later reconstruction, display and transmission. In certain embodiments, the memory circuit 170 may store one or more neural networks (e.g., deep learning-based reconstruction model such as unrolled deep learning-based reconstruction model deep learning-based mask estimating model). In certain embodiments, the disclosed techniques may occur on a separate computing device having processing circuitry and memory circuitry.

An additional interface circuit 172 may be provided for exchanging image data, configuration parameters, and so forth with external system components such as remote access and storage devices 108. Finally, the system control and analysis circuit 168 may be communicatively coupled to various peripheral devices for facilitating operator interface and for producing hard copies of the reconstructed images. In the illustrated embodiment, these peripherals include a printer 174, a monitor 176, and user interface 178 including devices such as a keyboard, a mouse, a touchscreen (e.g., integrated with the monitor 176), and so forth.

The present disclosure provides a model-based approach for solving model-based deep learning denoising. The problem of MR image reconstruction is solved as a mean squared error (MSE) problem with a data driven regularizer:

$${min}_{x} {‖ y - Ax ‖}_{2}^{2} s . t . x = z \qquad ( 1 )$$

where y is the observed k-space, x is the estimated image space data, A is the signal model which is M·F, where M is the data consistency mask and F is the Fourier transform, and z is the deep learning-based prior which is derived from the last iteration. Based on the above expression, the Lagrangian is obtained as:

$$ℒ = {min}_{x} {‖ y - Ax ‖}_{2}^{2} + λ {‖ x - z ‖}_{2}^{2} . \qquad ( 2 )$$

Obtaining the derivative of the above expression with respect to x and then finding the solution of

$$\frac{\partial ℒ}{\partial x} = 0 ,$$

the update step for ‘k+1’ iteration with respect to ‘k’ iteration is shown below:

$${x}_{k + 1} = \frac{{A}^{H} y + λ {z}_{k + 1}}{1 + λ} \qquad ( 3 )$$

where, zₖ₊₁=f_{θ}(xₖ). Here, θ are the deep learning parameters which are learnt over the unrolls, f_{θ}(⋅) is the deep learning network with parameters as θ, and xx is the output of the last iteration. In low signal-to-noise cases, the signal and noise distinction is occluded by high noise levels in the signal. In this case, the learnt prior ‘z’ is a deep learning network that learns the denoising operation.

In addition to performing a model-based deep learning denoising, the data consistency mask M is estimated which is responsible for enforcing the data consistency as part of the forward model A. Ideally, for the process of denoising, it desired to perturb the data to a greater extent with moving away from the low frequency region. However, rather than some fixed measure to do so, estimating the same from the data is preferred (since frequency content of the data and noise may the way the k-space shall be perturbed). Hence, estimating M is considered in this problem formulation. The optimization problem is then written as:

$${min}_{x , M} {‖ y - MFx ‖}_{2}^{2} s . t . x = z . \qquad ( 4 )$$

To solve for the variables in the above problem, we take an alternate optimization approach. Provided the noisy observation y, a continuous data consistency mask is utilized for model-based (unrolled) deep learning denoising. In a first step, \hat{M}=f_{θ}_{_{M}}(y), where θ_{M} are parameters of CNNs responsible for estimating data consistency mask, M. In a second step,

$${min}_{x} {‖ y - \hat{M} Fx ‖}_{2}^{2} s . t . x = z$$

as discussed above is utilized in a proximal mapping approach for solving model-based deep learning denoising, and the update steps are as stated for xₖ₊₁.

It is not desirable to have a similar mask for every noisy data. In other words, it is not desirable to treat each image the same. It can be understood that the function of the data consistency mask is to convey to the model-based deep learning denoising on which areas to perturb more compared to others. Naturally, low frequency regions representing contrast information are minimally perturbed (or not perturbed at all), and the mid and high frequency regions shall be perturbed more (e.g., progressively so) in a manner in which is best for the task of denoising. Hence, it is best for it to be estimated.

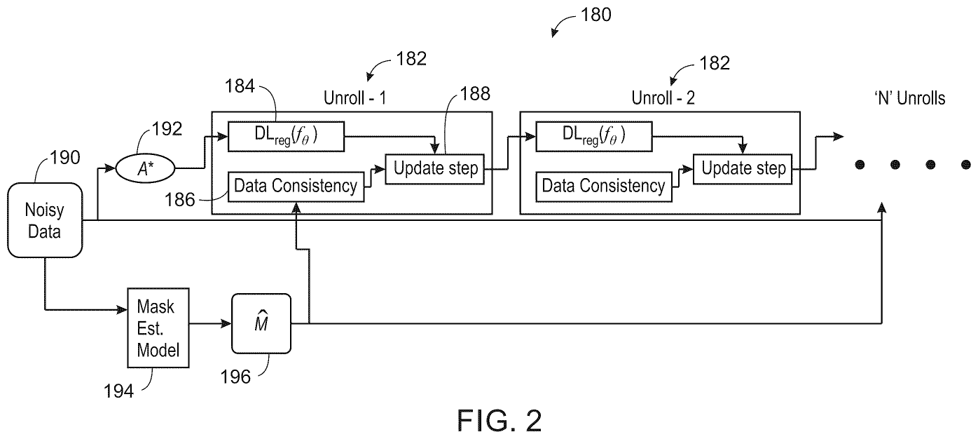

FIG. 2 is a schematic diagram illustrating reconstruction utilizing an estimated data consistency mask. FIG. 2 depicts an unrolled deep learning-based reconstruction model 180. As depicted, the unrolled deep learning-based reconstruction model 180 includes a number of unrolling steps (or unroll units) 182. Each unrolling step 182 includes a deep learning-based (e.g. CNN-based) regularizer unit 184 (DL_{reg}(f_{θ}) and a data consistency unit 186. In addition, each unrolling step 182 includes an update step 188.

The unrolled deep learning-based reconstruction model 180 has a two channel input. As depicted, noisy k-space data 190 is transformed into a noisy image as indicated by reference numeral 192 and is inputted into the regularizer unit 184 via one channel into the first unrolling step 182.

Also, the noisy k-space data 190 is inputted into a deep learning-based mask estimating model 194 (e.g., trained deep learning-based mask estimating model 194). The deep learning-based mask estimating model 194 estimates (and outputs) a data consistency mask 196 based on a frequency content of the noisy k-space data 190. Estimation of the data consistency mask 196 is a non-parametric estimation. The data consistency mask 196 is configured to convey to the deep learning-based reconstruction model 180 which regions of the noisy k-space data to perturb with low frequency regions being minimally perturbed or not perturbed and mid to high frequency regions being perturbed (in a progressive manner) relatively more than the low frequency regions. As opposed to a binary mask, the data consistency mask 196 has a continuous form (i.e., is a continuous data consistency mask with a continuous value or variable in a range between 0 and 1). In particular, the amount of perturbations conveyed by the data consistency mask 196 may vary over a continuum (i.e., have more than two discrete values). For example, the final output is normalized and ranges between 0 and 1.

In certain embodiments, the deep learning-based mask estimating model 194 is a simple CNN module. In certain embodiments, the deep learning-based mask estimating model 194 has 32 features and a depth of 8. The kernel size may be set at 3. Each feature layer is followed by a batch normalization two-dimensional layer and a rectified linear unit activation layer. There is a convolutional filter with a kernel size of 1 at the end of the CNN layers. The structure of deep learning-based mask estimating model 194 may vary.

In certain embodiments, the unrolled deep learning-based reconstruction model 180 includes 3 unrolling steps 182. Weights are shared across the unrolls. The updating step 188 occurs as outlined in Equation 3 above. In certain embodiments, a residual channel attention networks is used as the deep learning regularizer. The number of residual blocks and residual channels may be 5. There are two channel input/output networks (for real and imaginary). A kernel size of 3 is used for CNNs.

Also, the data consistency mask 196 is inputted into the data consistency unit 186 at each unrolling step 182 of the deep learning-based reconstruction model 180 (e.g., trained unrolled deep learning-based reconstruction model). The data consistency mask 196 is utilized for data consistency in each unrolling step 182 of the unrolled framework. The updating step 188 generates an output image that is passed onto the next unrolling step 182. Both the data consistency mask 196 and its weights are updated at each unrolling step 182 and passed on to next unrolling step 182.

The unrolled deep learning-based reconstruction model 180 outputs a reconstructed denoised image. In certain embodiments, the unrolled deep learning-based reconstruction model 180 outputs denoised k-space data. The unrolled deep learning-based reconstruction model 180 utilizes loss function. In particular, loss is imposed only on reconstructed images as illustrated in the following:

$$ℒ = {λ}_{1} ( {‖ Re ( \hat{I} ) - Re ( I ) ‖}_{1} + {‖ Im ( \hat{I} ) - Im ( I ) ‖}_{1} ) + {λ}_{2} SSIM ( abs ( \hat{I} ) , abs ( I ) ) \qquad ( 5 )$$

where Î and I are the estimated and ground truth images. In certain implementations (such as for generating the data below), λ₁=1.0 and λ₂=0.5 were used. In certain embodiments, both the unrolled deep learning-based reconstruction model 180 and the deep learning-based mask estimating model 194 are trained utilizing natural image datasets with simulation libraries. MR images were simulated from the natural images (e.g., like with autoregressive distributed lag (ARDL)).

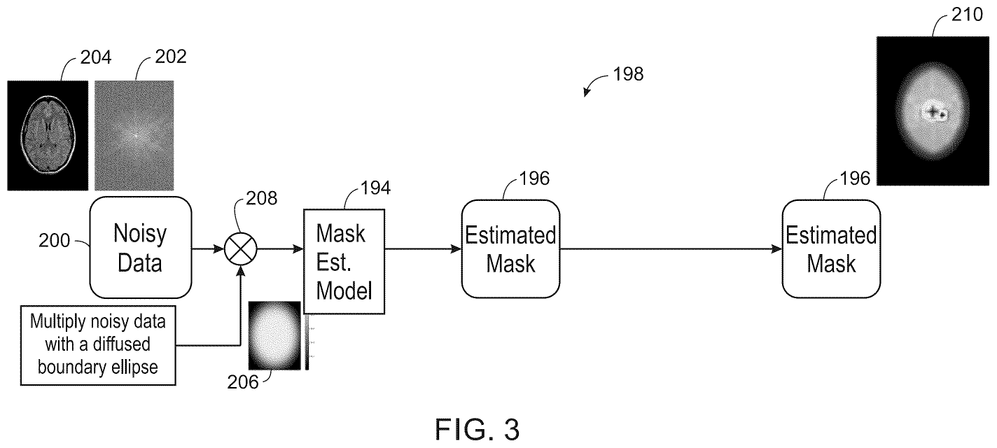

FIG. 3 is a schematic diagram of a method 198 for estimating a data consistency mask (e.g., without parametric assertions made). FIG. 3 illustrates a non-parametric realization of 194 the deep learning-based mask estimating model 194 in FIG. 2. Noisy k-space data 200 is obtained (e.g., acquired of a subject with an MR scanner). Image 202 depicts the noisy k-space data 200. Image 204 is a reconstructed image of the noisy k-space data 200. Prior to being inputted into the deep learning-based mask estimating model 194, the noisy k-space data 200 is multiplied with a diffused boundary ellipse 206 as indicated by reference numeral 208. Multiplying the noisy k-space data 200 with the diffused boundary ellipse 206 ensures only low frequency k-space data is utilized by the deep learning-based mask estimating model 194 in estimating the data consistency mask 196. The data consistency mask 196 is outputted by the deep learning-based mask estimating model 194. Estimation of the data consistency mask 196 is a non-parametric estimation. As depicted, the no parametric assertions are made on the data consistency mask 196 and it is utilized as outputted (e.g., predicted) by the deep learning-based mask estimating model 194. Image 210 is of the estimated data consistency mask. The data consistency mask 196 generated by the method 198 may be referred to M1 in the data presented below.

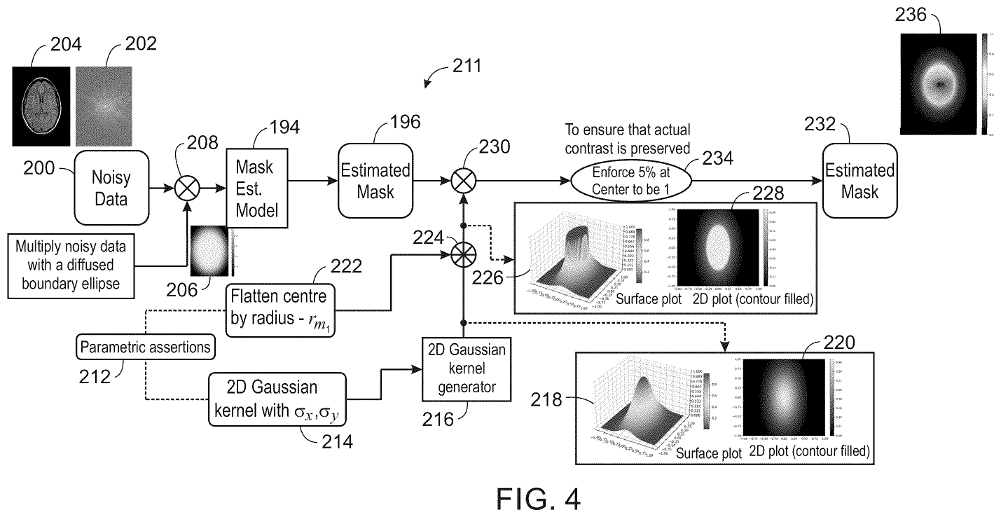

FIG. 4 is a schematic diagram of a method 211 for estimating a data consistency mask (e.g., with strong parametric assertions made). FIG. 4 illustrates a parametric realization of 194 the deep learning-based mask estimating model 194 in FIG. 2. Noisy k-space data 200 is obtained (e.g., acquired of a subject with an MR scanner). Image 202 depicts the noisy k-space data 200. Image 204 is a reconstructed image of the noisy k-space data 200. Prior to being inputted into the deep learning-based mask estimating model 194, the noisy k-space data 200 is multiplied with a diffused boundary ellipse 206 as indicated by reference numeral 208. Multiplying the noisy k-space data 200 with the diffused boundary ellipse 206 ensures only low frequency k-space data is utilized by the deep learning-based mask estimating model 194 in estimating the data consistency mask 196. The data consistency mask 196 is outputted by the deep learning-based mask estimating model 194. Estimation of the data consistency mask 196 is a non-parametric estimation.

As depicted, strong parametric assertions (i.e., assumptions) 212 are made on the data consistency mask 196. The parametric assertions 212 may vary from those depicted in FIG. 4. As depicted, the parametric assertions 212 includes utilizing a two-dimensional (2D) Gaussian kernel with σₓ, σ_{y} 214 which is generated with a 2D Gaussian kernel generator 216. Surface plot 218 and 2D plot 220 (which is contour filled) depict the 2D Gaussian kernel. Also, as depicted, the parametric assertions 212 include flattening the center by a radius, rₘ_{₁}, as indicated by reference numeral 222. The flattening of the center is applied to the 2D Gaussian kernel as indicated by reference numeral 224. Surface plot 226 and 2D plot 228 (which is contour filled) depict the modified 2D Gaussian kernel. The strong parametric assertions 212 are made on the data consistency mask 196 as indicated by reference numeral 230 in generating a modified data consistency mask 232. As indicated by reference numeral 234, to ensure that actual contrast is preserved, the strong parametric assertions 212 enforce that 5 percent of the data consistency mask at the center is 1. As depicted, strong parametric assertions 212 are made on the data consistency mask and it is utilized as modified by the deep learning-based mask estimating model 194. Image 236 is of the estimated data consistency mask. The modified data consistency mask 232 generated by the method 211 may be referred to M2 in the data presented below.

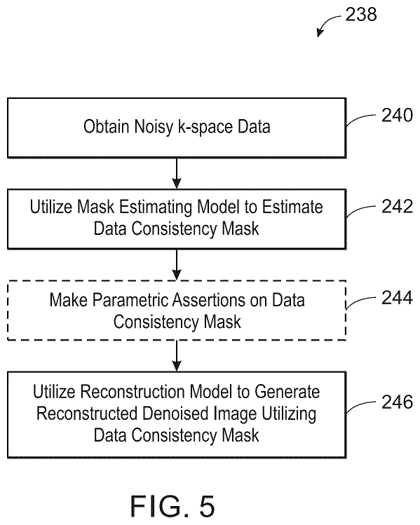

FIG. 5 illustrates a flow diagram of a method 238 for image processing of MR data. One or more steps of the method 238 may be performed by processing circuitry of the magnetic resonance imaging system 100 in FIG. 1 or a remote computing device. One or more of the steps of the method 238 may be performed simultaneously or in a different order from the order depicted in FIG. 5.

The method 238 includes obtaining noisy k-space data of a subject acquired with a magnetic resonance imaging (MRI) scanner (block 240). The method 238 also includes utilizing a deep learning-based mask estimating model to estimate a data consistency mask based on a frequency content of the noisy k-space data, wherein the data consistency mask is configured to be utilized in denoising the noisy k-space data (block 242). In certain embodiments, the no parametric assertions may be made on the data consistency mask prior to being utilized in an unrolled deep learning-based reconstruction model. In certain embodiments, the method 238 includes making parametric assertions (e.g., strong parametric assertions) on the data consistency mask to modify the data consistency mask prior to being utilized in an unrolled deep learning-based reconstruction model (block 244). The method 238 further includes utilizing a deep learning-based reconstruction model on the noisy k-space data to generate a reconstructed denoised image utilizing the data consistency mask (block 246).

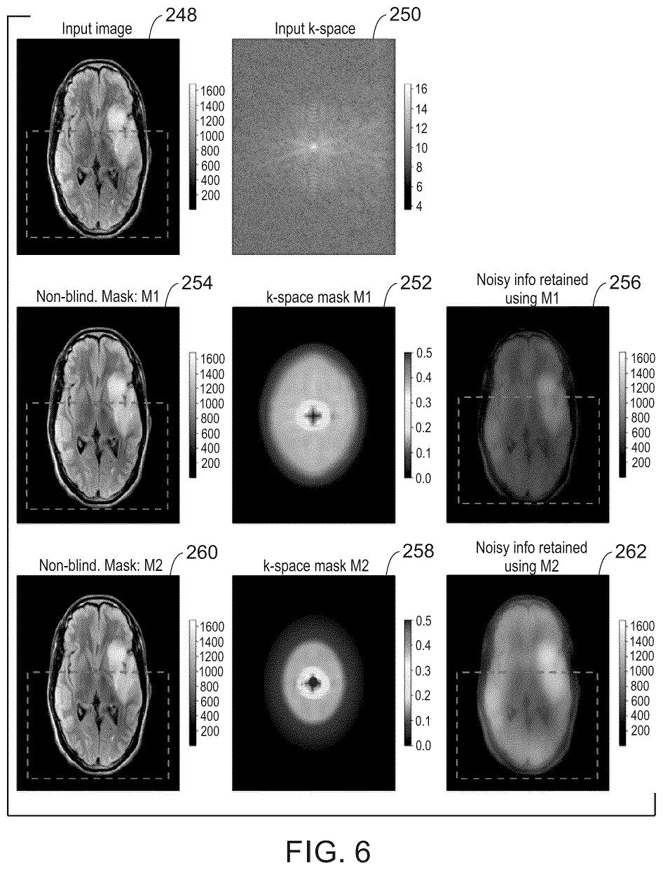

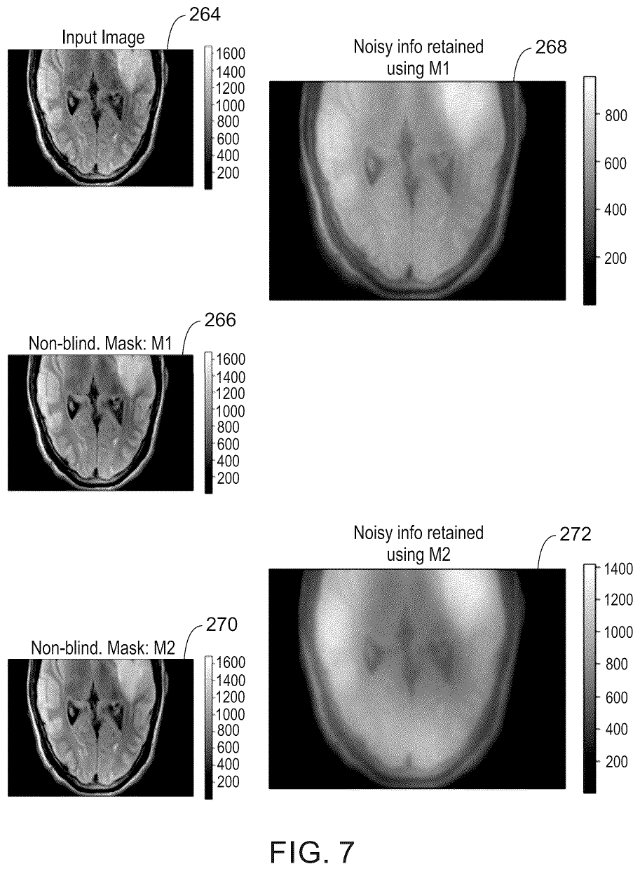

FIGS. 6 and 7 depict analysis of MR data utilizing the techniques described herein. The MR data is T2 FLAIR multi-channel data acquired of a brain. The analysis checks the content of the noisy image in the k-space mask regions obtained in the methods 198 and 211 described in FIGS. 3 and 4, respectively. Image 248 in FIG. 6 is the input image (i.e., noisy image). Image 250 in FIG. 6 is the input k-space data (i.e., noisy k-space data) from which the image 248 is obtained. Image 252 in FIG. 6 is the k-space mask (M1) obtained using the method 198. Image 254 in FIG. 6 is the denoised image outputted using the k-space mask (M1). Image 256 in FIG. 6 is the noisy information retained using the k-space mask (M1). Image 258 in FIG. 6 is the k-space mask (M2) obtained using the method 211. Image 260 in FIG. 6 is the denoised image outputted using the k-space mask (M2). Image 262 in FIG. 6 is the noisy information retained using the k-space mask (M2). Image 264 in FIG. 7 is a zoomed portion of the image 248 in FIG. 6. Image 266 in FIG. 7 is a zoomed portion of the image 254 in FIG. 6. Image 268 in FIG. 7 is a zoomed portion of the image 256 in FIG. 6. Image 270 in FIG. 7 is a zoomed portion of the image 260 in FIG. 6. Image 272 in FIG. 7 is a zoomed portion of the image 262 in FIG. 6. Utilizing either method 198, 211, the information retained from the noisy data has information of the structures that appears as a high signal-to-noise ratio version of the input image. The remaining information to obtain the denoised output is obtained from the regularizer output.

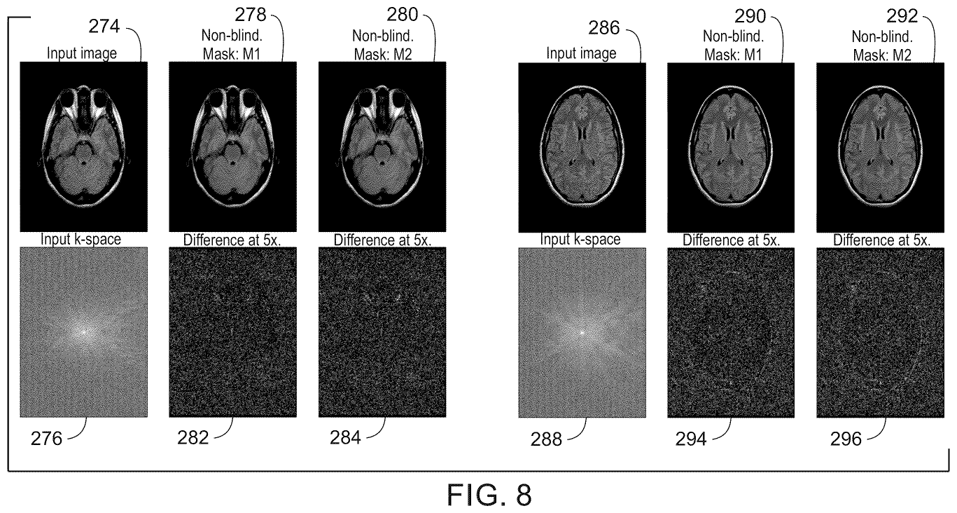

FIG. 8 depicts analysis of MR data utilizing the techniques described herein (e.g., in a very signal-to-noise ratio case). The MR data is T2 FLAIR data acquired of a brain at 1.5 Tesla with a body coil. The images on the left side of FIG. 8 are derived from one slice of a subject. The images on the right side of FIG. 8 are derived from another slice of the same subject. Image 274 is the input image (i.e., noisy image). Image 276 is the input k-space data (i.e., noisy k-space data) from which the image 274 is obtained. Image 278 is the denoised image outputted using a k-space mask (M1) obtained using the method 198 in FIG. 2. Image 280 is the denoised image outputted using a k-space mask (M2) obtained using the method 211 in FIG. 3. Image 282 is the difference between the image 274 and the image 278 at 5X. Image 284 is the difference between the image 274 and the image 280 at 5X. Of note is the residue precited by the deep learning. It is noise with no structures present in it as shown in images 282, 284. At the same time, the denoised image (images 278, 280) does not suffer the issue of over smoothening.

Image 286 is the input image (i.e., noisy image). Image 288 is the input k-space data (i.e., noisy k-space data) from which the image 286 is obtained. Image 290 is the denoised image outputted using a k-space mask (M1) obtained using the method 198 in FIG. 2. Image 292 is the denoised image outputted using a k-space mask (M2) obtained using the method 211 in FIG. 3. Image 294 is the difference between the image 286 and the image 290 at 5X. Image 296 is the difference between the image 286 and the image 292 at 5X. Of note is the residue precited by the deep learning. It is noise with no structures present in it as shown in images 294, 296. At the same time, the denoised image (images 290, 292) does not suffer the issue of over smoothening.

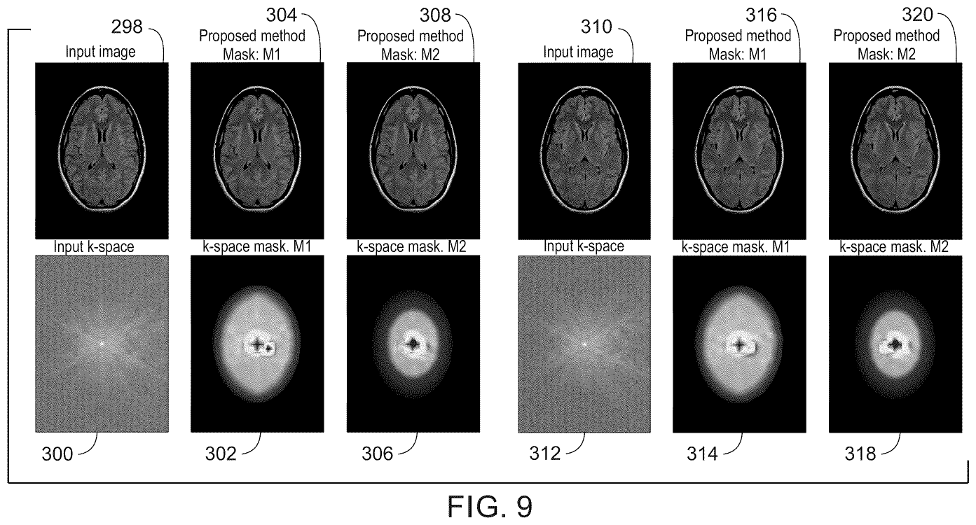

FIG. 9 depicts MR data obtained utilizing the techniques described herein. The MR data is T2 FLAIR data acquired of a brain at 1.5 Tesla with a body coil. The images on the left side of FIG. 9 are derived from one slice of a subject. The images on the right side of FIG. 9 are derived from another slice of the same subject. Image 298 is the input image (i.e., noisy image). Image 300 is the input k-space data (i.e., noisy k-space data) from which the image 298 is obtained. Image 302 in FIG. 9 is the k-space mask (M1) obtained using the method 198. Image 304 in FIG. 9 is the denoised image outputted using the k-space mask (M1). Image 306 in FIG. 9 is the k-space mask (M2) obtained using the method 211. Image 308 in FIG. 9 is the denoised image outputted using the k-space mask (M2).

Image 310 is the input image (i.e., noisy image). Image 312 is the input k-space data (i.e., noisy k-space data) from which the image 310 is obtained. Image 314 in FIG. 9 is the k-space mask (M1) obtained using the method 198. Image 316 in FIG. 9 is the denoised image outputted using the k-space mask (M1). Image 318 in FIG. 9 is the k-space mask (M2) obtained using the method 211. Image 320 in FIG. 9 is the denoised image outputted using the k-space mask (M2).

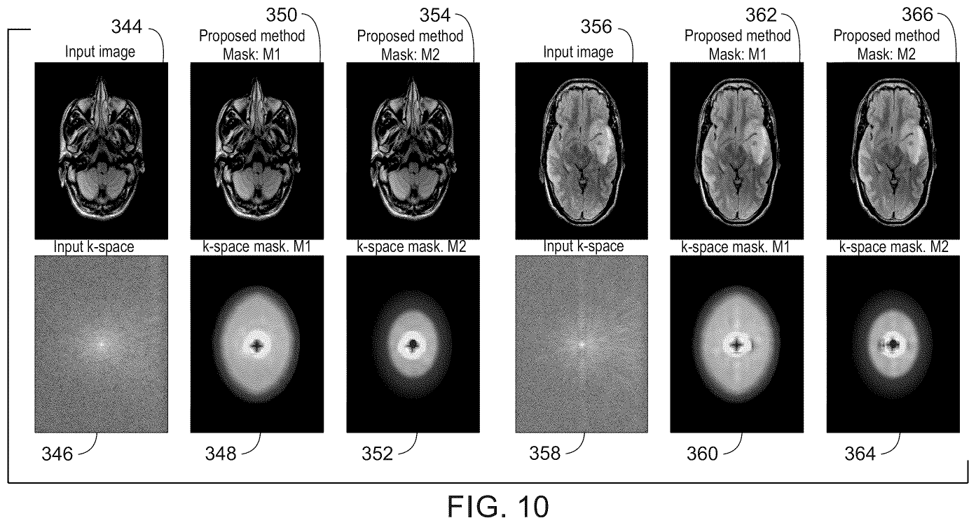

FIG. 10 depicts MR data obtained utilizing the techniques described herein (e.g., of the brain). The MR data is T2 FLAIR multi-channel data acquired of a brain The images on the left side of FIG. 10 are derived from one slice of a subject. The images on the right side of FIG. 10 are derived from another slice of the same subject. Image 344 is the input image (i.e., noisy image). Image 346 is the input k-space data (i.e., noisy k-space data) from which the image 344 is obtained. Image 348 in FIG. 10 is the k-space mask (M1) obtained using the method 198. Image 350 in FIG. 10 is the denoised image outputted using the k-space mask (M1). Image 352 in FIG. 10 is the k-space mask (M2) obtained using the method 211. Image 354 in FIG. 10 is the denoised image outputted using the k-space mask (M2).

Image 356 is the input image (i.e., noisy image). Image 358 is the input k-space data (i.e., noisy k-space data) from which the image 356 is obtained. Image 360 in FIG. 10 is the k-space mask (M1) obtained using the method 198. Image 362 in FIG. 10 is the denoised image outputted using the k-space mask (M1). Image 364 in FIG. 10 is the k-space mask (M2) obtained using the method 211. Image 366 in FIG. 10 is the denoised image outputted using the k-space mask (M2).

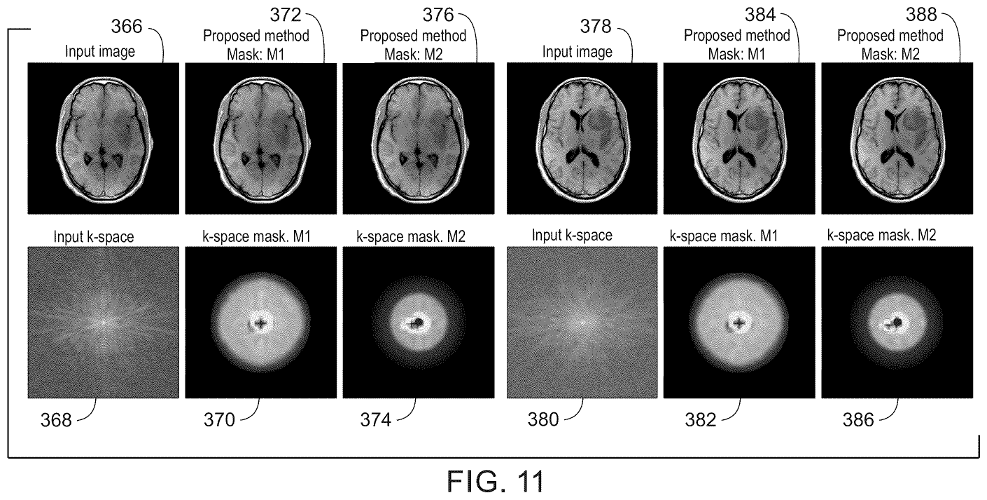

FIG. 11 depicts MR data obtained utilizing the techniques described herein (e.g., of the brain with T1 FSE). The MR data is T1 FSE multi-channel data acquired of a brain. The images on the left side of FIG. 11 are derived from one slice of a subject. The images on the right side of FIG. 11 are derived from another slice of the same subject. Image 366 is the input image (i.e., noisy image). Image 368 is the input k-space data (i.e., noisy k-space data) from which the image 366 is obtained. Image 370 in FIG. 11 is the k-space mask (M1) obtained using the method 198. Image 372 in FIG. 11 is the denoised image outputted using the k-space mask (M1). Image 374 in FIG. 11 is the k-space mask (M2) obtained using the method 211. Image 376 in FIG. 11 is the denoised image outputted using the k-space mask (M2).

Image 378 is the input image (i.e., noisy image). Image 380 is the input k-space data (i.e., noisy k-space data) from which the image 378 is obtained. Image 382 in FIG. 11 is the k-space mask (M1) obtained using the method 198. Image 384 in FIG. 11 is the denoised image outputted using the k-space mask (M1). Image 386 in FIG. 11 is the k-space mask (M2) obtained using the method 211. Image 388 in FIG. 11 is the denoised image outputted using the k-space mask (M2).

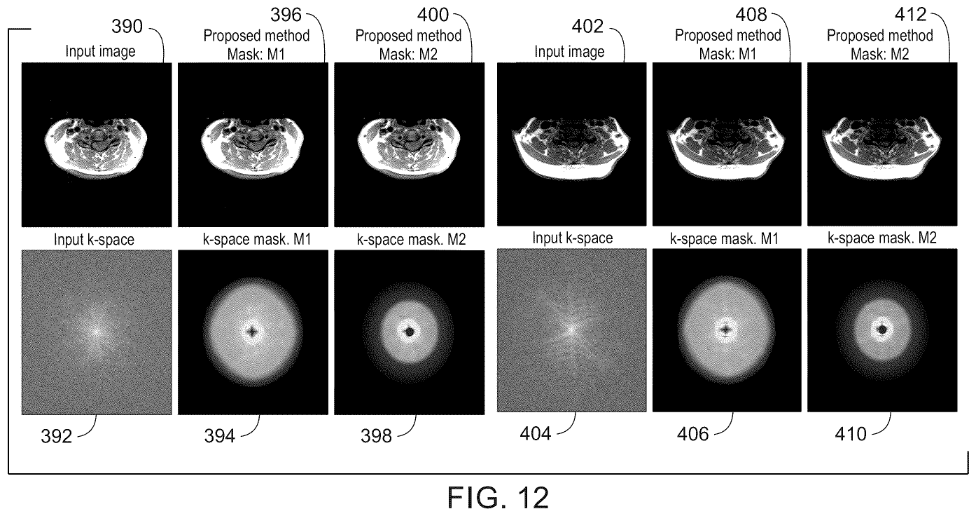

FIG. 12 depicts MR data obtained utilizing the techniques described herein (e.g., of the cervical spine with T1 FSE). The MR data is c-spine axial T1 FSE multi-channel data acquired of a cervical spine. The images on the left side of FIG. 12 are derived from one slice of a subject. The images on the right side of FIG. 12 are derived from another slice of the same subject. Image 390 is the input image (i.e., noisy image). Image 392 is the input k-space data (i.e., noisy k-space data) from which the image 390 is obtained. Image 394 in FIG. 12 is the k-space mask (M1) obtained using the method 198. Image 396 in FIG. 12 is the denoised image outputted using the k-space mask (M1). Image 398 in FIG. 12 is the k-space mask (M2) obtained using the method 211. Image 400 in FIG. 12 is the denoised image outputted using the k-space mask (M2).

Image 402 is the input image (i.e., noisy image). Image 404 is the input k-space data (i.e., noisy k-space data) from which the image 402 is obtained. Image 406 in FIG. 12 is the k-space mask (M1) obtained using the method 198. Image 408 in FIG. 12 is the denoised image outputted using the k-space mask (M1). Image 410 in FIG. 12 is the k-space mask (M2) obtained using the method 211. Image 412 in FIG. 12 is the denoised image outputted using the k-space mask (M2).

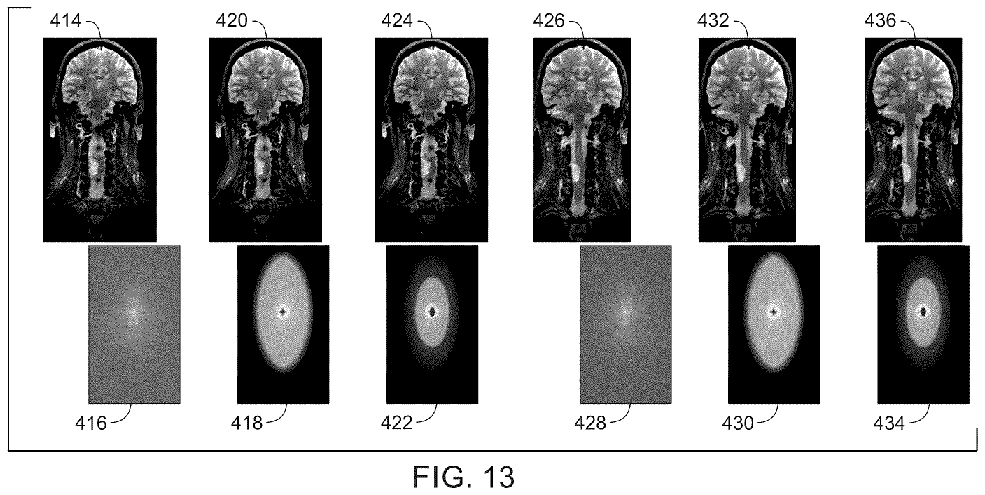

FIG. 13 depicts MR data obtained utilizing the techniques described herein (e.g., of the cervical spine with T2 STIR). The MR data is c-spine coronal T2 STIR multi-channel data acquired of a cervical spine. The images on the left side of FIG. 13 are derived from one slice of a subject. The images on the right side of FIG. 13 are derived from another slice of the same subject. Image 414 is the input image (i.e., noisy image). Image 416 is the input k-space data (i.e., noisy k-space data) from which the image 414 is obtained. Image 418 in FIG. 13 is the k-space mask (M1) obtained using the method 198. Image 420 in FIG. 13 is the denoised image outputted using the k-space mask (M1). Image 422 in FIG. 13 is the k-space mask (M2) obtained using the method 211. Image 424 in FIG. 13 is the denoised image outputted using the k-space mask (M2).

Image 426 is the input image (i.e., noisy image). Image 428 is the input k-space data (i.e., noisy k-space data) from which the image 426 is obtained. Image 430 in FIG. 13 is the k-space mask (M1) obtained using the method 198. Image 432 in FIG. 13 is the denoised image outputted using the k-space mask (M1). Image 434 in FIG. 13 is the k-space mask (M2) obtained using the method 211. Image 436 in FIG. 13 is the denoised image outputted using the k-space mask (M2).

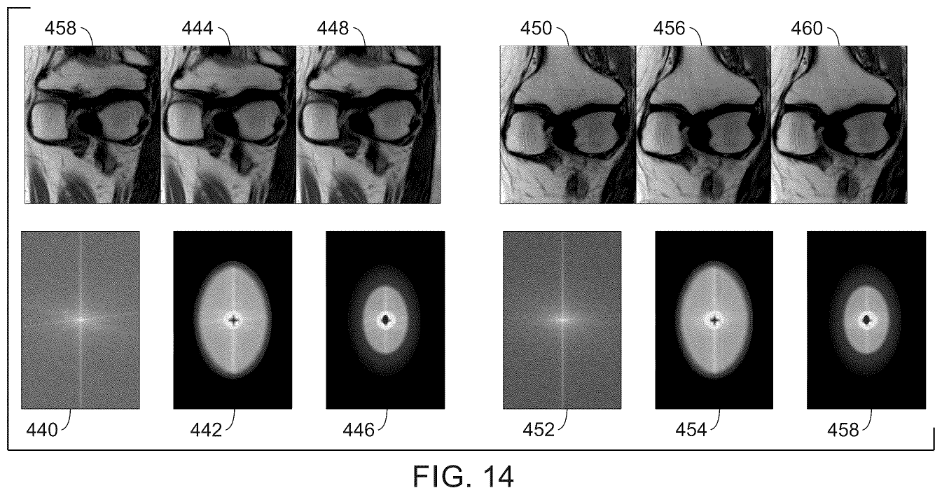

FIG. 14 depicts MR data obtained utilizing the techniques described herein (e.g., of the knee with T1 FSE). The MR data is coronal T1 FSE multi-channel data acquired of a knee. The images on the left side of FIG. 14 are derived from one slice of a subject. The images on the right side of FIG. 14 are derived from another slice of the same subject. Image 438 is the input image (i.e., noisy image). Image 440 is the input k-space data (i.e., noisy k-space data) from which the image 438 is obtained. Image 442 in FIG. 14 is the k-space mask (M1) obtained using the method 198. Image 444 in FIG. 14 is the denoised image outputted using the k-space mask (M1). Image 446 in FIG. 14 is the k-space mask (M2) obtained using the method 211. Image 448 in FIG. 14 is the denoised image outputted using the k-space mask (M2).

Image 450 is the input image (i.e., noisy image). Image 452 is the input k-space data (i.e., noisy k-space data) from which the image 450 is obtained. Image 454 in FIG. 14 is the k-space mask (M1) obtained using the method 198. Image 456 in FIG. 14 is the denoised image outputted using the k-space mask (M1). Image 458 in FIG. 14 is the k-space mask (M2) obtained using the method 211. Image 460 in FIG. 14 is the denoised image outputted using the k-space mask (M2).

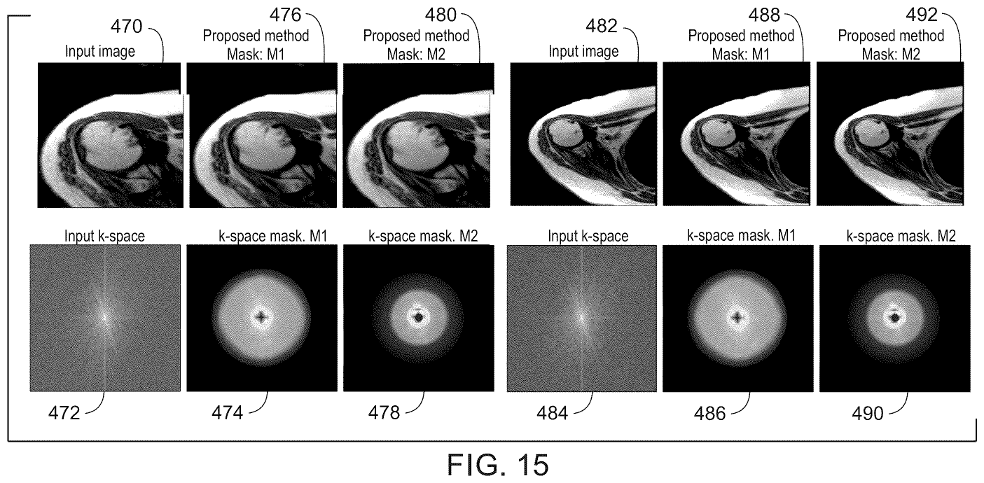

FIG. 15 depicts MR data obtained utilizing the techniques described herein (e.g., of the shoulder with T1 FSE). The MR data is axial T1 FSE multi-channel data acquired of a shoulder. The images on the left side of FIG. 15 are derived from one slice of a subject. The images on the right side of FIG. 15 are derived from another slice of the same subject. Image 470 is the input image (i.e., noisy image). Image 472 is the input k-space data (i.e., noisy k-space data) from which the image 470 is obtained. Image 474 in FIG. 15 is the k-space mask (M1) obtained using the method 198. Image 476 in FIG. 15 is the denoised image outputted using the k-space mask (M1). Image 478 in FIG. 15 is the k-space mask (M2) obtained using the method 211. Image 480 in FIG. 15 is the denoised image outputted using the k-space mask (M2).

Image 482 is the input image (i.e., noisy image). Image 484 is the input k-space data (i.e., noisy k-space data) from which the image 482 is obtained. Image 486 in FIG. 15 is the k-space mask (M1) obtained using the method 198. Image 488 in FIG. 15 is the denoised image outputted using the k-space mask (M1). Image 490 in FIG. 15 is the k-space mask (M2) obtained using the method 211. Image 492 in FIG. 15 is the denoised image outputted using the k-space mask (M2).

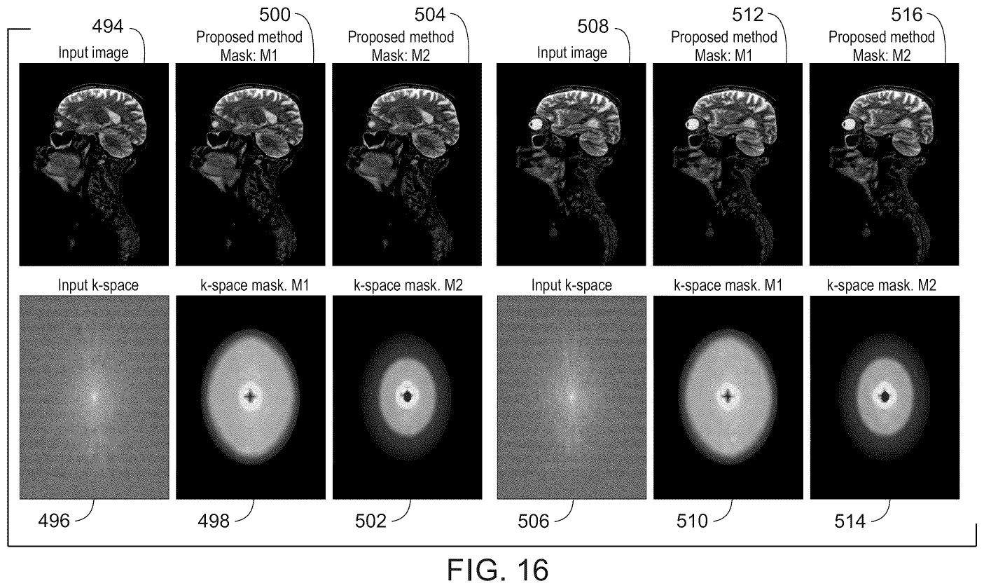

FIG. 16 depicts MR data obtained utilizing the techniques described herein (e.g., of the neck with T2 STIR). The MR data is sagittal T2 STIR multi-channel data acquired of a neck. The images on the left side of FIG. 16 are derived from one slice of a subject. The images on the right side of FIG. 16 are derived from another slice of the same subject. Image 494 is the input image (i.e., noisy image). Image 496 is the input k-space data (i.e., noisy k-space data) from which the image 494 is obtained. Image 498 in FIG. 16 is the k-space mask (M1) obtained using the method 198. Image 500 in FIG. 16 is the denoised image outputted using the k-space mask (M1). Image 502 in FIG. 16 is the k-space mask (M2) obtained using the method 211. Image 504 in FIG. 16 is the denoised image outputted using the k-space mask (M2).

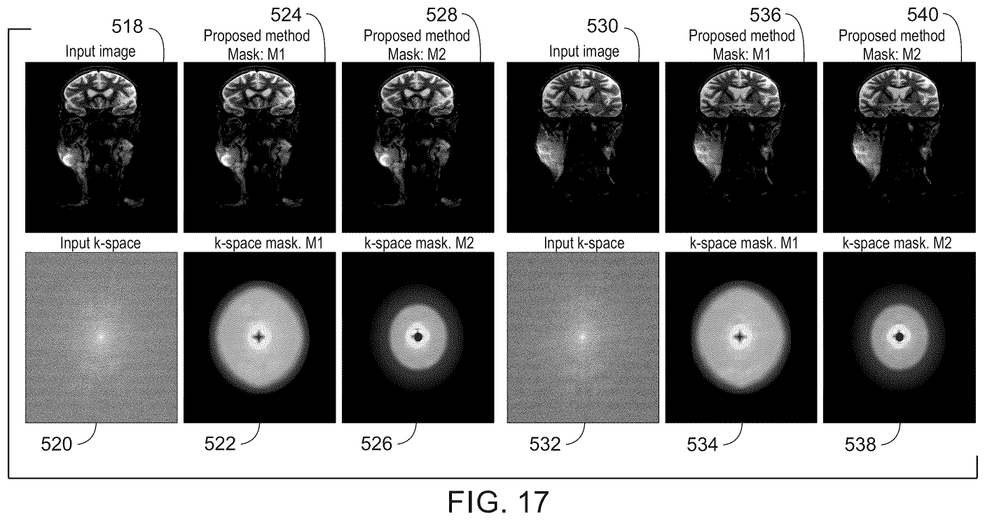

Image 506 is the input image (i.e., noisy image). Image 508 is the input k-space data (i.e., noisy k-space data) from which the image 506 is obtained. Image 510 in FIG. 17 is the k-space mask (M1) obtained using the method 198. Image 512 in FIG. 16 is the denoised image outputted using the k-space mask (M1). Image 514 in FIG. 16 is the k-space mask (M2) obtained using the method 211. Image 516 in FIG. 16 is the denoised image outputted using the k-space mask (M2).

FIG. 17 depicts MR data obtained utilizing the techniques described herein (e.g., of the neck with T2 STIR). The MR data is coronal T2 STIR multi-channel data acquired of a neck. The images on the left side of FIG. 17 are derived from one slice of a subject. The images on the right side of FIG. 17 are derived from another slice of the same subject. Image 518 is the input image (i.e., noisy image). Image 520 is the input k-space data (i.e., noisy k-space data) from which the image 518 is obtained. Image 522 in FIG. 17 is the k-space mask (M1) obtained using the method 198. Image 524 in FIG. 17 is the denoised image outputted using the k-space mask (M1). Image 526 in FIG. 17 is the k-space mask (M2) obtained using the method 211. Image 528 in FIG. 17 is the denoised image outputted using the k-space mask (M2).

Image 530 is the input image (i.e., noisy image). Image 532 is the input k-space data (i.e., noisy k-space data) from which the image 530 is obtained. Image 534 in FIG. 17 is the k-space mask (M1) obtained using the method 198. Image 536 in FIG. 17 is the denoised image outputted using the k-space mask (M1). Image 538 in FIG. 17 is the k-space mask (M2) obtained using the method 211. Image 540 in FIG. 17 is the denoised image outputted using the k-space mask (M2).

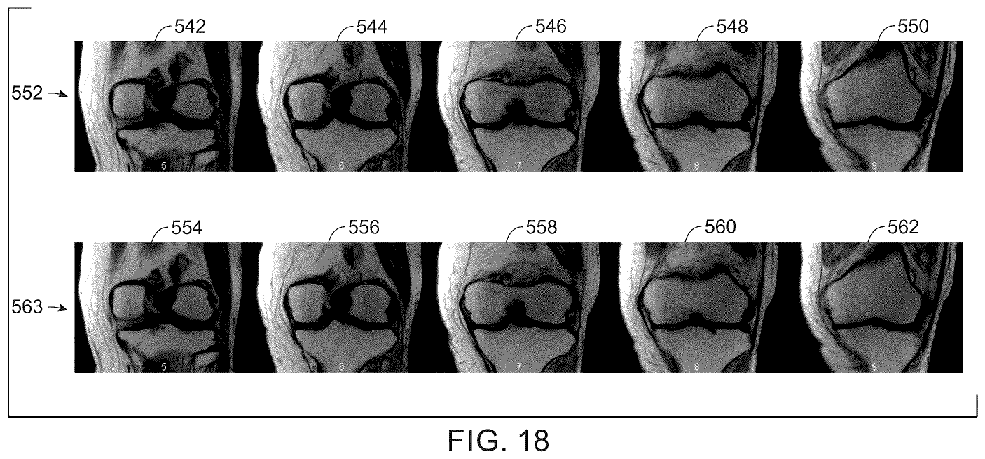

FIG. 18 depicts noisy MR data compared to MR data denoised utilizing the techniques described herein (e.g., of the knee with T1 FSE). The MR data is coronal T1 FSE data acquired of a knee. Images 542, 544, 546, 548, and 550 in a top row 552 are noisy images of different slices of the knee of the same subject. Images 554, 556, 558, 560, and 562 in a bottom row 563 are the corresponding denoised images of the images 542, 544, 546, 548, and 550 that were denoised utilizing the technique described in FIG. 2. No de-ringing was performed on the images. In the images 554, 556, 558, 560, and 562, no effacement of structures occurred due to denoising.

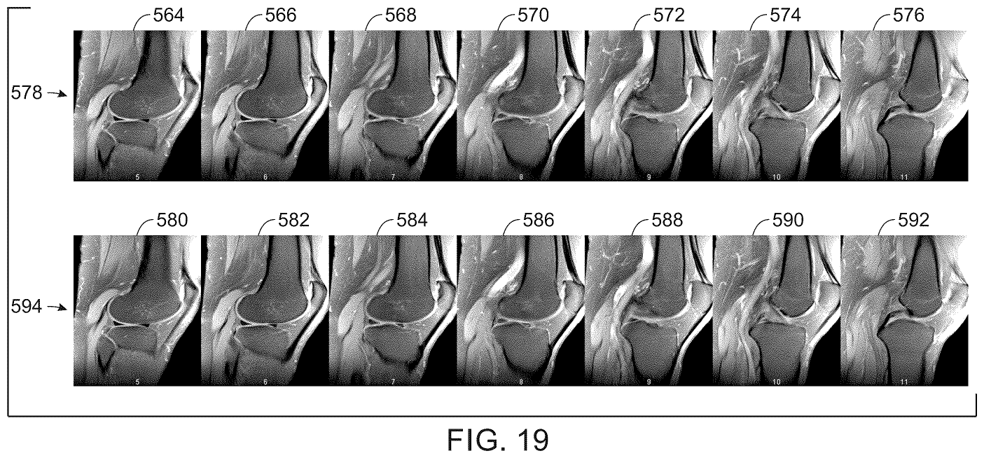

FIG. 19 depicts noisy MR data compared to MR data denoised utilizing the techniques described herein (e.g., of the knee with sagittal T1 FSE). The MR data is sagittal T1 FSE data acquired of a knee at 1.5 Tesla. Images 564, 566, 568, 570, 572, 574, and 576 in a top row 578 are noisy images of different slices of the knee of the same subject. Images 580, 582, 584, 586, 588, 590, and 592 in a bottom row 594 are the corresponding denoised images of the images 564, 566, 568, 570, 572, 574, and 576 that were denoised utilizing the technique described in FIG. 2 . . . . In the images 580, 582, 584, 586, 588, 590, and 592, no effacement of structures occurred due to denoising.

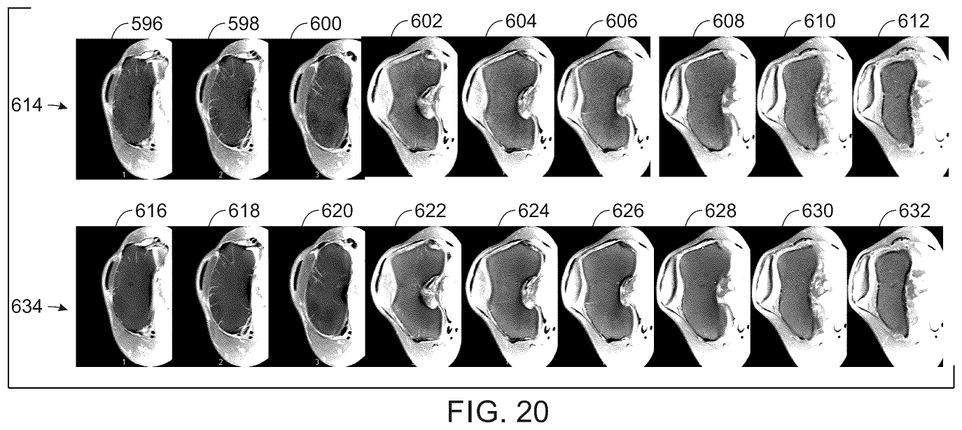

FIG. 20 depicts noisy MR data compared to MR data denoised utilizing the techniques described herein (e.g., of the knee with axial T1 FSE). The MR data is axial T1 FSE data acquired of a knee at 1.5 Tesla. Images 596, 598, 600, 602, 604, 606, 608, 610, and 612 in a top row 614 are noisy images of different slices of the knee of the same subject. Images 616, 618, 620, 622, 624, 626, 628, 630, and 632 in a bottom row 634 are the corresponding denoised images of the images 596, 598, 600, 602, 604, 606, 608, 610, and 612 that were denoised utilizing the technique described in FIG. 2. In the images 616, 618, 620, 622, 624, 626, 628, 630, and 632, no effacement of structures occurred due to denoising.

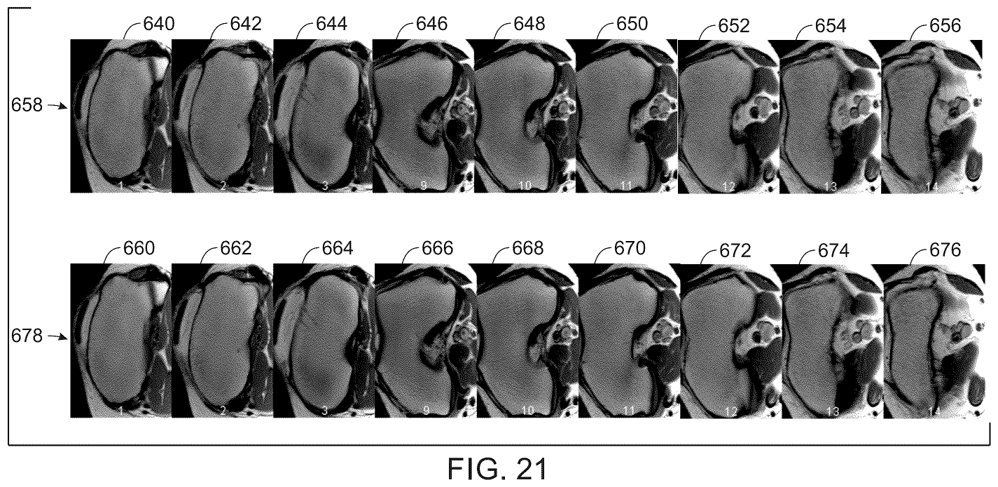

FIG. 21 depicts noisy MR data compared to MR data denoised (with controlled denoising for high signal-to-noise ratio images) utilizing the techniques described herein (e.g., of the knee with axial T1 FSE). The MR data is axial T1 FSE data acquired of a knee at 1.5 Tesla. Images 640, 642, 644, 646, 648, 650, 652, 654, and 656 in a top row 658 are noisy images of different slices of the knee of the same subject. Images 660, 662, 664, 666, 668, 670, 672, 674, and 676 in a bottom row 678 are the corresponding denoised images of the images 640, 642, 644, 646, 648, 650, 652, 654, and 656 that were denoised utilizing the technique described in FIG. 2. In the images 660, 662, 664, 666, 668, 670, 672, 674, and 676, no effacement of structures occurred due to denoising.

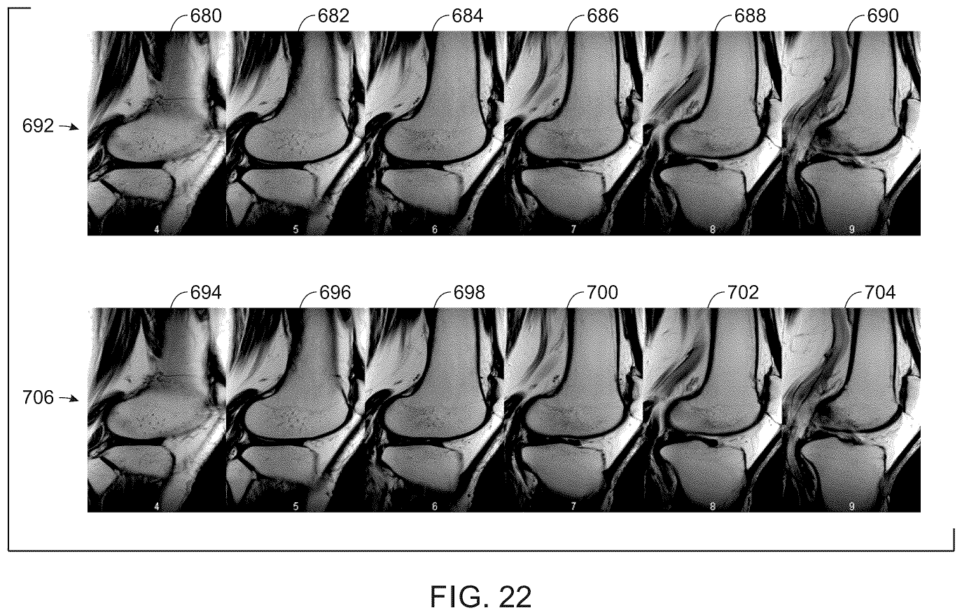

FIG. 22 depicts noisy MR data compared to MR data denoised (with controlled denoising for high signal-to-noise ratio images) utilizing the techniques described herein (e.g., of the knee with sagittal T1 FSE). The MR data is sagittal T1 FSE data acquired of a knee at 1.5 Tesla. Images 680, 682, 684, 686, 688, and 690 in a top row 692 are noisy images of different slices of the knee of the same subject. Images 694, 696, 698, 700, 702, and 704 in a bottom row 706 are the corresponding denoised images of the images 680, 682, 684, 686, 688, and 690 that were denoised utilizing the technique described in FIG. 2. In the images 694, 696, 698, 700, 702, and 704, no effacement of structures occurred due to denoising.

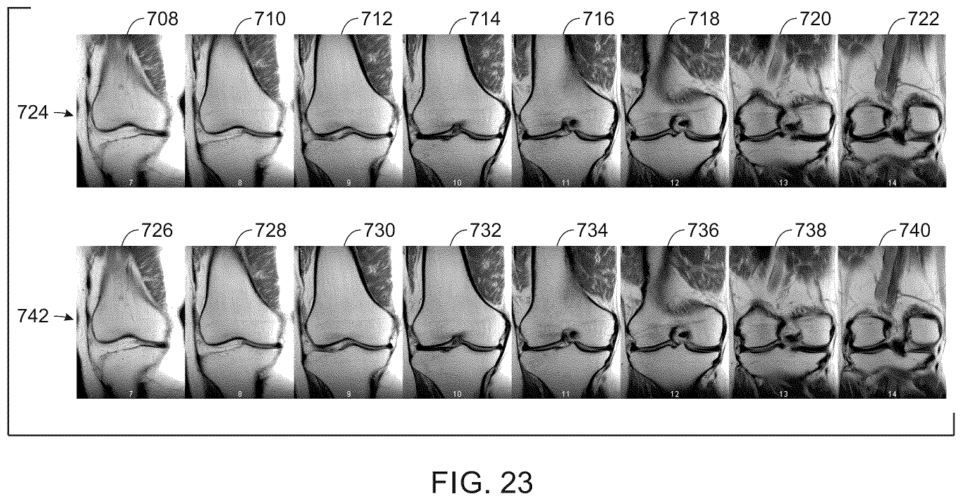

FIG. 23 depicts noisy MR data compared to MR data denoised (with controlled denoising for high signal-to-noise ratio images) utilizing the techniques described herein (e.g., of the knee with coronal T1 FSE). The MR data is coronal T1 FSE data acquired of a knee at 1.5 Tesla. Images 708, 710, 712, 714, 716, 718, 720, and 722 in a top row 724 are noisy images of different slices of the knee of the same subject. Images 726, 728, 730, 732, 734, 736, 738, and 740 in a bottom row 742 are the corresponding denoised images of the images 708, 710, 712, 714, 716, 718, 720, and 722 that were denoised utilizing the technique described in FIG. 2. In the images 726, 728, 730, 732, 734, 736, 738, and 740, no effacement of structures occurred due to denoising.

Technical effects of the disclosed subject matter include providing high image quality images which improves the diagnostic quality of the images (and potentially reduces image reading times). Technical effects of the disclosed subject matter also includes providing the ability to reliably denoise very low signal-to-noise ratio images. This provides the ability to have diagnostic quality images from high resolution single average magnetic resonance imaging data (thus, providing better quality images from less scan time). This also provides reliable performance for sequence which operate in low signal-to-noise regimes.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform] in [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

This written description uses examples to disclose the present subject matter, including the best mode, and also to enable any person skilled in the art to practice the subject matter, including making and using any devices or systems and performing any incorporated methods. The patentable scope of the subject matter is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A computer-implemented method, comprising:
obtaining, via a processing system comprising one or more processors, noisy k-space data of a subject acquired with a magnetic resonance imaging (MRI) scanner;
utilizing, via the processing system, a deep learning-based mask estimating model to estimate a data consistency mask based on a frequency content of the noisy k-space data, wherein the data consistency mask is configured to be utilized in denoising the noisy k-space data in a model-based deep learning manner; and
utilizing, via the processing system, a deep learning-based reconstruction model on the noisy k-space data to generate a reconstructed denoised image utilizing the data consistency mask.

2. The computer-implemented method of claim 1, wherein the deep learning-based reconstruction model comprises an unrolled framework, and wherein utilizing the deep learning-based reconstruction model on the noisy k-space data comprises:
inputting both the noisy k-space and the estimated data consistency mask into the deep learning-based reconstruction model, wherein the data consistency mask is utilized for data consistency in each unroll unit of the unrolled framework; and
outputting from the deep learning-based reconstruction model the reconstructed denoised image or denoise k-space.

3. The computer-implemented method of claim 2, wherein both the data consistency mask and its weights are updated at each unroll unit.

4. The computer-implemented method of claim 2, wherein the data consistency mask is configured to convey to the deep learning-based reconstruction model which regions of the noisy k-space to perturb with low frequency regions being minimally perturbed or not perturbed and mid to high frequency regions being perturbed relatively more than the low frequency regions.

5. The computer-implemented method of claim 1, wherein the data consistency mask has a continuous data value in a range of 0 to 1.

6. The computer-implemented method of claim 1, wherein utilizing the deep learning-based mask estimating model to estimate the data consistency mask comprises multiplying the noisy k-space data with a diffused boundary ellipse prior to inputting the noisy k-space data into the deep learning-based mask estimating model so that only low frequency k-space data is utilized by the deep learning-based mask estimating model in estimating the data consistency mask.

7. The computer-implemented method of claim 6, wherein estimation of the data consistency mask is a non-parametric estimation.

8. The computer-implemented method of claim 7, wherein the data consistency mask is configured to be utilized in denoising the noisy k-space data without parametric assertions made on the data consistency mask.

9. The computer-implemented method of claim 7, wherein the data consistency mask is configured to be utilized in denoising the noisy k-space data with parametric assertions made on the data consistency mask.

10. A system, comprising:
a memory encoding processor-executable routines; and
a processing system comprising one or more processors and configured to access the memory and to execute the processor-executable routines, wherein the processor-executable routines, when executed by the processing system, cause the processing system to:
obtain noisy k-space data of a subject acquired with a magnetic resonance imaging (MRI) scanner;
utilize a deep learning-based mask estimating model to estimate a data consistency mask based on a frequency content of the noisy k-space data, wherein the data consistency mask is configured to be utilized in denoising the noisy k-space data in a model-based deep learning manner; and
utilize a deep learning-based reconstruction model on the noisy k-space data to generate a reconstructed denoised image utilizing the data consistency mask.

11. The system of claim 10, wherein the deep learning-based reconstruction model comprises an unrolled framework, and wherein utilizing the deep learning-based reconstruction model on the noisy k-space data comprises:
inputting both the noisy k-space data and the data consistency mask into the deep learning-based reconstruction model, wherein the data consistency mask is utilized for data consistency in each unroll unit of the unrolled framework; and
outputting from the deep learning-based reconstruction model the reconstructed denoised image or denoised k-space.

12. The system of claim 11, wherein the data consistency mask is configured to convey to the deep learning-based reconstruction model which regions of the noisy k-space to perturb with low frequency regions being minimally perturbed or not perturbed and mid to high frequency regions being perturbed relatively more than the low frequency regions.

13. The system of claim 10, wherein the data consistency mask has a continuous data value in a range of 0 to 1.

14. The system of claim 10, wherein utilizing the deep learning-based mask estimating model to estimate the data consistency mask comprises multiplying the noisy k-space data with a diffused boundary ellipse prior to inputting the noisy k-space data into the deep learning-based mask estimating model so that only low frequency k-space data is utilized by the deep learning-based mask estimating model in estimating the data consistency mask.

15. The system of claim 14, wherein estimation of the data consistency mask is a non-parametric estimation.

16. The system of claim 15, wherein the data consistency mask is configured to be utilized in denoising the noisy k-space data without parametric assertions made on the data consistency mask.

17. The system of claim 15, wherein the data consistency mask is configured to be utilized in denoising the noisy k-space data with parametric assertions made on the data consistency mask.

18. A non-transitory computer-readable medium, the non-transitory computer-readable medium comprising processor-executable code that when executed by a processing system comprising one or more processors, causes the processing system to:
obtain noisy k-space data of a subject acquired with a magnetic resonance imaging (MRI) scanner;
utilize a deep learning-based mask estimating model to estimate a data consistency mask based on a frequency content of the noisy k-space data, wherein the data consistency mask is configured to be utilized in denoising the noisy k-space data in a model-based deep learning manner; and
utilize a deep learning-based reconstruction model on the noisy k-space data to generate a reconstructed denoised image utilizing the data consistency mask.

19. The non-transitory computer-readable medium of claim 18, wherein the deep learning-based reconstruction model comprises an unrolled framework, and wherein utilizing the deep learning-based reconstruction model on the noisy k-space data comprises:
inputting both the noisy k-space data and the data consistency mask into the deep learning-based reconstruction model, wherein the data consistency mask is utilized for data consistency in each unroll unit of the unrolled framework; and
outputting from the deep learning-based reconstruction model the reconstructed denoised image or denoised k-space.

20. The non-transitory computer-readable medium of claim 19, wherein the data consistency mask is configured to convey to the deep learning-based reconstruction model which regions of the noisy k-space to perturb with low frequency regions being minimally perturbed or not perturbed and mid to high frequency regions being perturbed relatively more than the low frequency regions.
